(19) United States
(12) Patent Application Publication
(10) Pub. No.: US 2008/0116589 A1
(43) Pub. Date: May 22, 2008

(54) Ball grid array package assembly with integrated voltage regulator

(76) Inventors: Zong-Fu Li, Mesa, AZ (US); David England, Maricopa, AZ (US); Bobby Nikjou, Tempe, AZ (US); Joseph T. Dibene, Olympia, WA (US); Hong Xie, Phoenix, AZ (US); Jason Zhang, Mesa, AZ (US)

Correspondence Address: TROP PRUNER & HU, PC, 1616 S. VOSS ROAD, SUITE 750, HOUSTON, TX, 77057-2631, US

(21) Appl. No.: 11/601,266

(22) Filed: Nov. 17, 2006

(51) Int. Cl. H01L 23/48; H01L 21/00; H01L 21/44

(52) U.S. Cl. 257/780; 257/773; 438/107; 438/613

(57) ABSTRACT

An integrated voltage regulator may be provided on the bottom of a ball grid array processor package. This may be done despite the fact that conventionally integrated voltage regulator chips are too thick to fit in the area normally available between the motherboard and the ball grid array package because that area is defined by solder balls of a necessarily limited height which is conventionally believed to be too small to accommodate the integrated voltage regulator.

### BACKGROUND

This relates to computer systems and, more particularly, to providing supply voltages to power integrated circuits such as a processor.

Advances in integrated circuit technology continue to provide faster, more robust, more densely packed integrated circuits. With each technological advance, power delivery, input/output, and thermal solutions become problematic.

A socket may be used to couple a processor to a system board, such as a motherboard. A number of leads connect the various input/output ports on the processor to various buses, control lines, and power lines on the system board. Each lead has associated with it a certain amount of inductance. Inductance, related to the length of leads, must be below a certain critical inductance level in order for input and output operations to work properly. The critical inductance decreases as the operating frequency of the processor increases. The maximum allowable length of the leads tends to decrease as operating frequency increases.

A voltage regulator provides the power delivery solution for the processor. Processors usually operate at different voltage levels and tolerance levels than those typically provided by most power supplies used in computer systems.

Processors also commonly consume power at a higher rate than most power supplies provide. The amount of power that a processor consumes depends on clock speed and transistor density. A voltage regulator may not only convert power to appropriate voltage and tolerance levels, but also supplies power at the required slew rate. Capacitors may store power from the power supply so that it can be provided at a rate faster slew rate. The amount of capacitance needed to sustain the slew rate increases as the slew rate increases and increases as the distance between capacitors and the processor increases. Larger capacitance may mean larger and/or more capacitors must be provided.

Because the voltage regulator needs to be as close as possible to the processor to provide power at the required slew rate and in an efficient manner, it is advantageous to use an integrated voltage regulator that provides power proximate to the processor. For example, in connection with pin grid array circuits, an integrated voltage regulator may be provided within a socket that couples the processor package to a motherboard. The socket provides sufficient vertical height to receive the integrated voltage regulator so that the voltage regulator can be mounted on the bottom of the pin grid array package.

Increasingly, ball grid array packages are becoming more popular. They have many advantages, including lower costs and much smaller package sizes. However, ball grid arrays generally must have solder balls of a certain size to achieve the desired input/output density. As a result, the size of the solder balls tends to be too small to receive an integrated voltage regulator below the processor package.

### BRIEF DESCRIPTION OF THE DRAWINGS

FIG. 1 is an enlarged, partial, cross-sectional view of one embodiment of the present invention;

FIG. 2 is an enlarged, partial, cross-sectional view of another embodiment of the present invention; and

FIG. 3 is a system depiction for both embodiments of the present invention illustrated in FIGS. 1 and 2.

### DETAILED DESCRIPTION

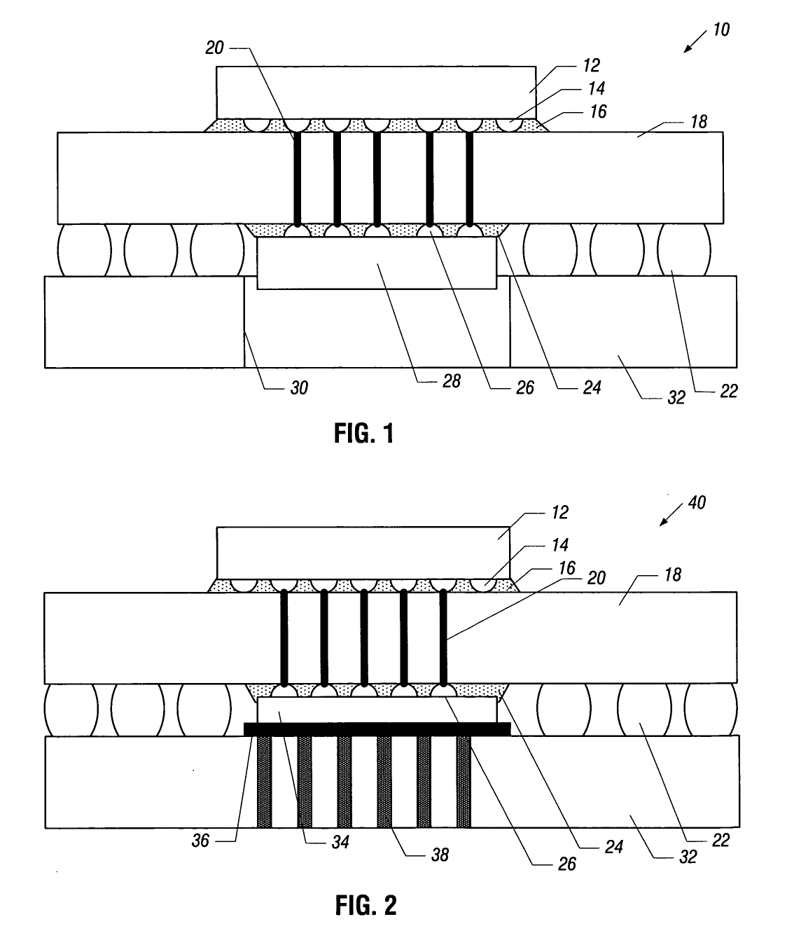

Referring to FIG. 1, a computer system 10 may be formed on a system or motherboard 32. A motherboard is a printed circuit board on which are mounted a number of components, including a processor. All or part of a computer system may be mounted on or below the motherboard. In particular, a processor package may be mounted with a ball grid array, flip chip, or C4 packaging on top of the motherboard 32. The processor ball grid array package may be coupled by solder balls 22 to appropriate lands on the motherboard 32. In addition, the solder balls 22 may electrically and mechanically couple to lands (not shown) on the ball grid array package 18. The ball grid array package 18, in turn, electrically couples to a processor integrated circuit 12 by solder balls 14. Underfill material 16 may be provided between the processor integrated circuit 12 and the ball grid array package 18, in one embodiment, to seal out atmospheric moisture.

Some of the balls 14 on the integrated circuit 12 may connect via vias 20 through the package 18 to balls 26 on an integrated voltage regulator 28. The integrated voltage regulator 28 may be a bare (unpackaged) die mounted on the bottom of the ball grid array package 18 so that it is in close proximity to the integrated circuit 12. The integrated voltage regulator 28, in some embodiments, may include not only the voltage regulator, but also on-chip decoupling capacitors, a pulse width modulation circuit, and the inductors integrated within one package. An underfill 24 may be provided between the voltage regulator 28 and the ball grid array package 18 to seal the region therebetween.

The balls 22 must be of a certain size in order to obtain the desired density of inputs and outputs between the motherboard 32 and the integrated circuit 12. As a result, in some cases, the solder ball height, for the desired input/output density, may be too small to fit the integrated voltage regulator 28 on the bottom of the package 18 without interfering with the motherboard 32. Again, it is desirable to locate the integrated voltage regulator 28 on the bottom of the package 18 for the electrical performance reasons described previously.

In one embodiment, a recess 30 may be formed in the motherboard 32 to receive the integrated voltage regulator 28 when the package is placed on the motherboard. For example, the package may be surface mounted to the motherboard. It may be positioned by a pick-and-place machine in the appropriate position on the motherboard. In this position, the integrated voltage regulator 28 fits in the recess 30. Then heat may be applied to solder the package to the motherboard 32, thereby fixing the integrated voltage regulator 28 at least partially within the hole 30 in the motherboard 32.

The motherboard recess 30 may be formed by various techniques, including drilling, etching, laser drilling, and punching. The recess 30 may partially or completely penetrate the motherboard 32.

In accordance with another embodiment, in a system 40, also involving a ball grid array integrated circuit package and its securement to a motherboard with an intervening integrated voltage regulator, referring to FIG. 2, the integrated voltage regulator 34 may be made of a sufficiently reduced vertical height that it can actually fit within the region defined between the package 18 and the motherboard 32 by the height of the solder balls 22. This may be achieved by reducing the thickness of the integrated voltage regulator die. This height reduction may be done by forming the die in conventional fashion and then simply grinding off the back side of the die to thin the die down to the thickness needed to fit within the gap between the ball grid array package and the motherboard 32, given the necessary vertical height of the solder balls 22 once surface mounted to the motherboard and the ball grid array package. That is, generally the vertical height of the solder balls 22 will reduce as a result of surface mounting and it is this height that is critical in determining the final thickness of the integrated voltage regulator 34 die.

As shown in FIG. 2, the integrated voltage regulator 34 may be thermally coupled to the motherboard 32 by a thermal interface material, such as a metal or ceramic based material, that may include a thermal pad and conducting grease 36 in one embodiment. Thus, a good thermal connection may be made from the integrated voltage regulator 34 to the motherboard 32. The thermal pad may be graphite or self-gluing thermal tape, to mention two examples, while the conducting grease may, for example, include silicone.

Formed through the motherboard 32 are a plurality of thermal vias 38. The thermal vias 38 may be formed by drilling vias through the motherboard 38 and then filling the vias with a thermally conductive material, such as a metal, including one or more of copper, gold, or aluminum. As a result, heat is transmitted from the integrated voltage regulator 34 externally of the package and the motherboard. This heat may arise from the operation of the integrated voltage regulator 34, as well as heat transferred from the integrated circuit 12 and otherwise blocked from dissipation by the intervening voltage regulator 34.

In both embodiments described above, conventionally, a heat sink would be provided over the integrated circuit 12 to dissipate heat upwardly away from the package.

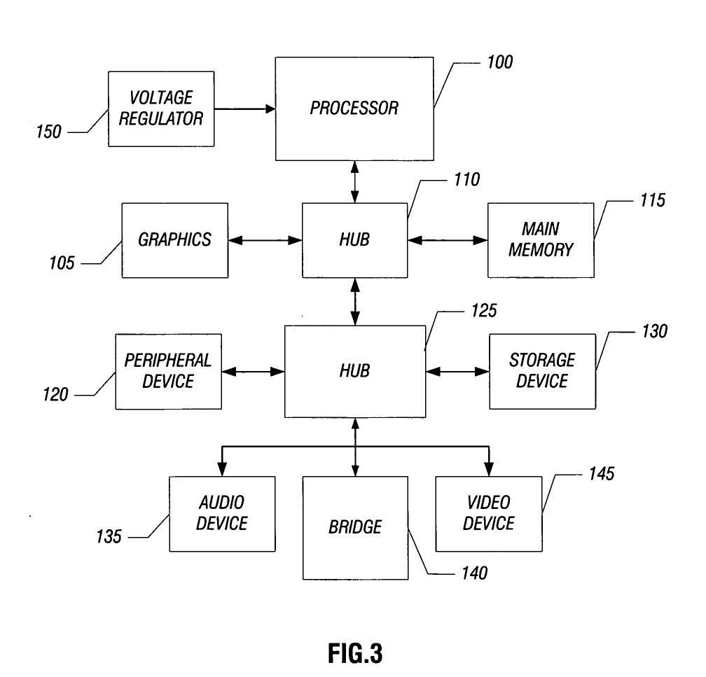

Referring to FIG. 3, a computer system may be formed in accordance with one embodiment. The computer system may include a processor 100 coupled to hub 110. The processor 100 may be powered by one or more voltages from the voltage regulator 150. The processor 100 may communicate with a graphics controller 105, main memory 115, and hub 125 via hub 110. Hub 125 may couple peripheral device 120, storage device 130, audio device 135, video device 145, and bridge 140 to a hub 110. The bridge 140 may couple hub 125 to one or more additional buses coupled to one or more additional peripheral devices. Note that in accordance with other embodiments of the present invention, the computer system may include more or fewer components than those shown in FIG. 3 and may include a vast variety of other components arranged in any of a variety of architectures.

In accordance with one embodiment, the voltage regulator 150 is an integrated voltage regulator that is external to the processor 100. The voltage regulator 150 may provide one or more supply voltages to the processor 100 alone or in addition to providing one or more supply voltages to other components of the computer system. In addition, there may be one or more additional voltage regulators that provide one or more additional supply voltages to the processor. The voltage regulator may be an integrated voltage regulator, as in the case of the voltage regulators 28 and 34, shown in FIGS. 1 and 2. The processor may be implemented by the ball grid array package 18 and the integrated circuit 12 in some embodiments of the present invention.

Thus, in some embodiments, the voltage regulator may be thicker in a vertical direction than the solder balls joining the package to the board. In one such embodiment, the system board may include a recess to accommodate the regulator. In some embodiments, the recess may extend completely through the system board. In other cases, the recess may not extend all the way through the board. If the recess does not extend completely through the board, a thermal via may be installed under the voltage regulator through the remaining portion of the board, below the recess.

In some embodiments, the regulator may have a thickness in the vertical direction that is less than or equal to the vertical height of the solder balls when coupled between the board and the package. In such cases, a thermal interface material may be used between the board and the regulator. In some cases, the thermal interface may be used to conduct heat through the board from said voltage regulator.

As still another possibility, a donut-shaped interposer may be used to extend the solder balls and to pass the regulator through a central opening in the interposer. The interposer may be positioned between the package 18 and the board 32. It may be coupled by solder balls to the board and the package. The interposer may provide additional vertical space to accommodate the voltage regulator.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
mounting an integrated voltage regulator below a ball grid array processor package.

2. The method of claim 1 including thinning a semiconductor die to form the integrated voltage regulator to be mounted below said package.

3. The method of claim 1 including forming a recess in a system board to accommodate said integrated voltage regulator.

4. The method of claim 3 wherein forming a recess includes forming a hole through said system board to accommodate said regulator.

5. The method of claim 1 including using solder balls to couple a system board to said package.

6. The method of claim 5 including causing the integrated voltage regulator to fit within a vertical space defined by the height of the solder balls.

7. The method of claim 5 including making the voltage regulator thickness less than the thickness in a vertical direction of said solder balls.

8. The method of claim 7 including coupling said regulator to thermal vias in said board.

9. An integrated circuit package comprising:
a substrate;
solder balls coupled to said substrate;
an integrated circuit over said substrate and coupled to said substrate; and
an integrated voltage regulator coupled to said substrate between said solder balls.

10. The package of claim 9 wherein said circuit is a processor.

11. The package of claim 9 wherein said regulator is coupled to said substrate by additional solder balls.

12. The package of claim 9 wherein the height of said solder balls is greater than or equal to the height of said regulator.

13. The package of claim 12 wherein the height of said solder balls is greater than the height of said regulator.

14. The package of claim 9 wherein the height of said regulator is greater than the height of said solder balls.

15. A system board comprising:
an integrated circuit;
a circuit package coupled to said circuit;
a printed circuit board coupled to said package by solder balls; and
an integrated voltage regulator between said printed circuit board and said package.

16. The board of claim 15 wherein said voltage regulator is thicker in the vertical direction than said solder balls.

17. The board of claim 15 wherein said voltage regulator has a thickness less than or equal to the vertical height of said solder balls.

18. The board of claim 15 including a recess in said board to receive said regulator.

19. The board of claim 15 including thermal vias coupled to said voltage regulator.

20. A computer system comprising:
a system board;
a dynamic random access memory coupled to said system board;
a processor package coupled to said processor and coupled to said board by solder balls; and
an integrated voltage regulator coupled between said package and said board.

21. The system of claim 20 including a recess in said board to accommodate said regulator.

22. The system of claim 20 wherein said regulator has a height less than the height of said solder balls.

23. The system of claim 20 wherein said regulator has a height greater than the height of said solder balls.

24. The system of claim 20 wherein said regulator is between said solder balls.

25. The system of claim 20 including thermal vias in said board thermally coupled to said regulator.
